(19) United States
(12) Patent Application Publication
(10) Pub. No.: US 2012/0185071 A1
(43) Pub. Date: Jul. 19, 2012

(54) METHOD AND APPARATUS FOR IDENTIFYING ACCESSARIES USING NON-CONTACT INTERFACE

(75) Inventor: Hee-Jun KWON, Seoul (KR)

(73) Assignee: SAMSUNG ELECTRONICS CO., LTD., Gyeonggi-Do (KR)

(21) Appl. No.: 13/349,626

(22) Filed: Jan. 13, 2012

(30) Foreign Application Priority Data
Jan. 13, 2011 (KR) 10-2011-0003441

(51) Int. Cl. G06F 17/00; G06F 15/16; G01R 33/06

(52) U.S. Cl. 700/94; 324/251; 709/227

(57) ABSTRACT

The present invention relates to non-contact interface and, in a method for identifying peripheral accessories to perform different modes of function, the method comprises determining if a hall switch located at a previously defined location detects a magnetic field and identifying the function mode based on the location of the hall switch that detected the magnetic field.

### CLAIM OF PRIORITY

The present application is related to and claims priority under 35 U.S.C. §119 to an application filed in the Korean Intellectual Property Office on Jan. 13, 2011 and assigned Serial No. 10-2011-0003441, the contents of which are incorporated herein by reference.

### BACKGROUND OF THE INVENTION

1. Field of the Invention

The present invention relates to a method and an apparatus for identifying an operation mode of a portable device.

2. Description of the Related Art

In portable devices comprising a communication terminal, a contact point has been typically used in identifying an operation mode of a terminal or a peripheral accessory apparatus. For example, the portable device identifies an ear phone using contact point to which an ear phone is connected when the ear phone is connected to the portable device.

Hence, an improved method and an apparatus for identifying a peripheral accessory apparatus using non-contact point interface in portable devices are desired.

### SUMMARY OF THE INVENTION

An aspect of the present invention is to address at least the above-mentioned problems and/or disadvantages and to provide at least the advantages described below. Accordingly, an aspect of the present invention is to provide an apparatus and a method for identifying accessories using non-contact point interface.

Another aspect of the present invention is to provide a method and an apparatus in which a portable device comprising a mobile communication terminal identifies a specific accessory apparatus and executes a function suitable for the accessory apparatus when the portable device is connected to the accessory apparatus using a non-contact point interface.

According to an aspect of the present invention, a method for identifying a peripheral accessory apparatus using a non-contact interface may comprise determining if a hall switch located at a previously defined location detects a magnetic field and identifying the type of peripheral accessory apparatus based on the previously defined location information when the hall switch detects the magnetic field.

According to another aspect of the present invention, an apparatus for identifying a peripheral accessory apparatus using a non-contact interface may comprise a hall switch located at a previously defined location and a controlling unit for identifying the type of peripheral accessory apparatus based on the previously defined location information if the hall switch detects the magnetic field.

According to yet another aspect of the present invention, a method for identifying device mode type of a terminal having a plurality of hall switches provided at a plurality of predefined locations thereon and being received in a receiver via a non-contact interfacing, the receiver having a plurality of magnets provided at the corresponding locations of the plurality of hall switches includes: determining if a particular hall switch located at a particular location detects a magnetic field when a terminal is received in the receiver; and identifying the device mode type based on when the particular hall switch detects the magnetic field at the particular location.

According to another aspect of the present invention, an apparatus for identifying a device mode via a non-contact interfacing includes: at least one hall switch for detecting a magnetic field at a previously defined location; and a controlling unit for identifying the device mode based on a location where the at least one hall switch detects the magnetic field.

According to another aspect of the present invention, a system for providing a non-contact interface includes: a terminal having a plurality of hall switches provided at a plurality of predefined locations thereon; and a stand having a plurality of magnets thereon provided at corresponding locations of the plurality of hall switches, so that if a particular hall switch located at the terminal at a particular location detects a magnetic field when the terminal is received in the stand, an operation mode type of the terminal is determined and the terminal operates according to the determination outcome.

Other aspects, advantages and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of certain exemplary embodiments of the present invention will be more apparent from the following detailed description taken in conjunction with the accompanying drawings, in which:

FIG. 1 shows a portable device according to an embodiment of the present invention.

FIG. 2 shows a peripheral accessory apparatus of a portable device according to the present invention.

FIGS. 3A and 3B shows a flowchart illustrating a process for identifying a peripheral accessory apparatus of a portable device according to an embodiment of the present invention.

FIG. 4 shows a block configuration according to an embodiment of the present invention.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide.

As described below, the teachings of the present invention is to provide a method and an apparatus for identifying accessories using non-contact point interface.

In regarding to portable devices comprising a communication terminal, the commercialization of non-contact charging scheme is in progress and the use of non-contact interface is being increased.

The present invention relates to a method and an apparatus for identifying a peripheral accessory apparatus using a sensor of a portable device and executing a function suitable for the accessory apparatus automatically when general stand and non-contact point interface are used.

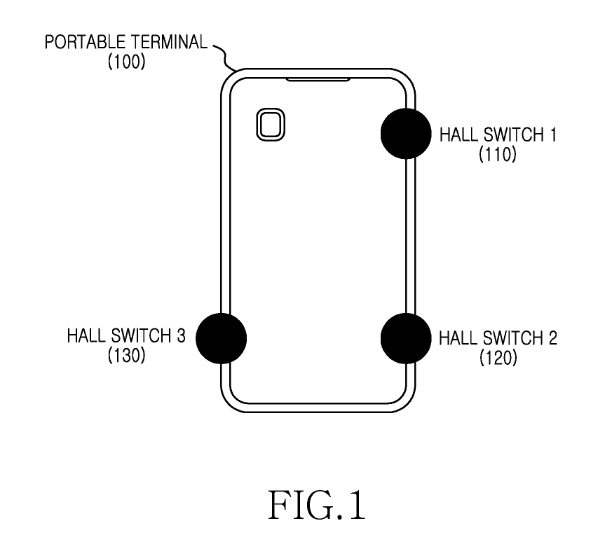

FIG. 1 shows a portable device according to an embodiment of the present invention.

Referring to FIG. 1, a portable device according to the present invention may be a portable terminal 100 having at least three Hall Switches 110,120 and 130.

Hall Switch 110, 120 and 130 may detect magnetic field, and the location of Hall Switch may be predefined in advance. Therefore, a predetermined function may be executed according to the instruction/activation of Hall Switch 100, 120 or 130 when they detect magnetic field.

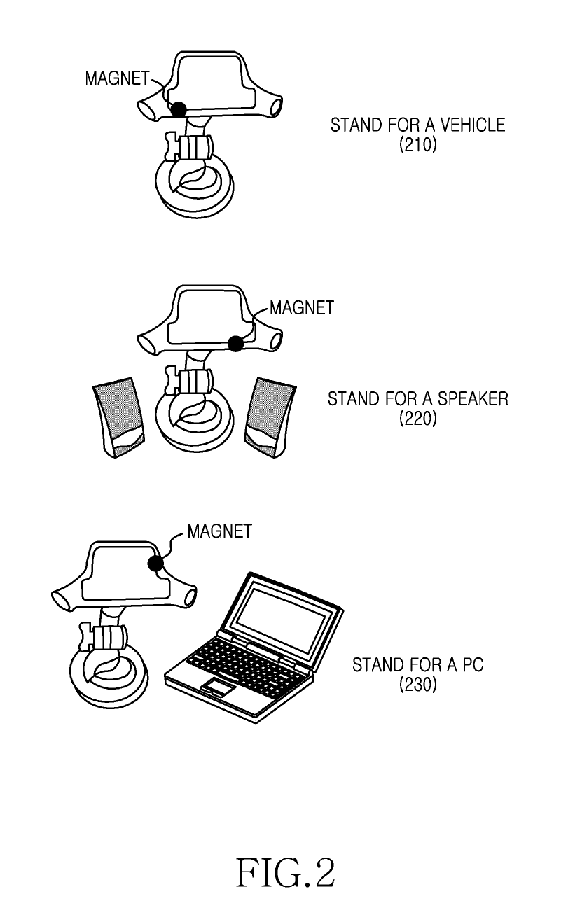

FIG. 2 shows a peripheral accessory apparatus of a portable device according to the present invention. In particular, it shows different embodiments where the teachings of the present invention may be applicable, but it should be noted other devices capable of receiving a device according to the present invention can be utilized. Thus, the illustrative examples in FIG. 2 should not limit the scope of the invention. As shown, an accessory apparatus 210 illustrates an example of a stand for vehicle, and as an illustrative example, a magnet may be placed at left bottom of the stand. It should be noted that the teachings of the present invention is applicable to other devices capable of receiving a terminal.

An Accessory apparatus 220 illustrates an example of a speaker stand where a magnet may be placed at right bottom of the stand.

An accessory apparatus 230 illustrates an example of PC stand where a magnet maybe placed at upper right area of the stand.

In the above examples, the speaker stand 220 and PC stand 230 may be connected to a speaker and a PC, respectively, using Near Field Communication Protocol (for example, Bluetooth and NFC).

As shown, the type of operation mode can differ based on the location of magnetic field sensed by a portable terminal when housed in a stand. For example, when a lower left bottom hall switch of the terminal senses the magnetic field thereto, the terminal operates determines that it's a stand for a vehicle and activates a navigation mode. If a lower right bottom hall switch senses the magnetic field, the terminal activates a multimedia mode. If an upper right hall switch senses the magnetic field, a computer mode is activates. Note that a presence of magnetic field at more than one hall switch or at other location can be programmed to activate other mode of the terminal during operation.

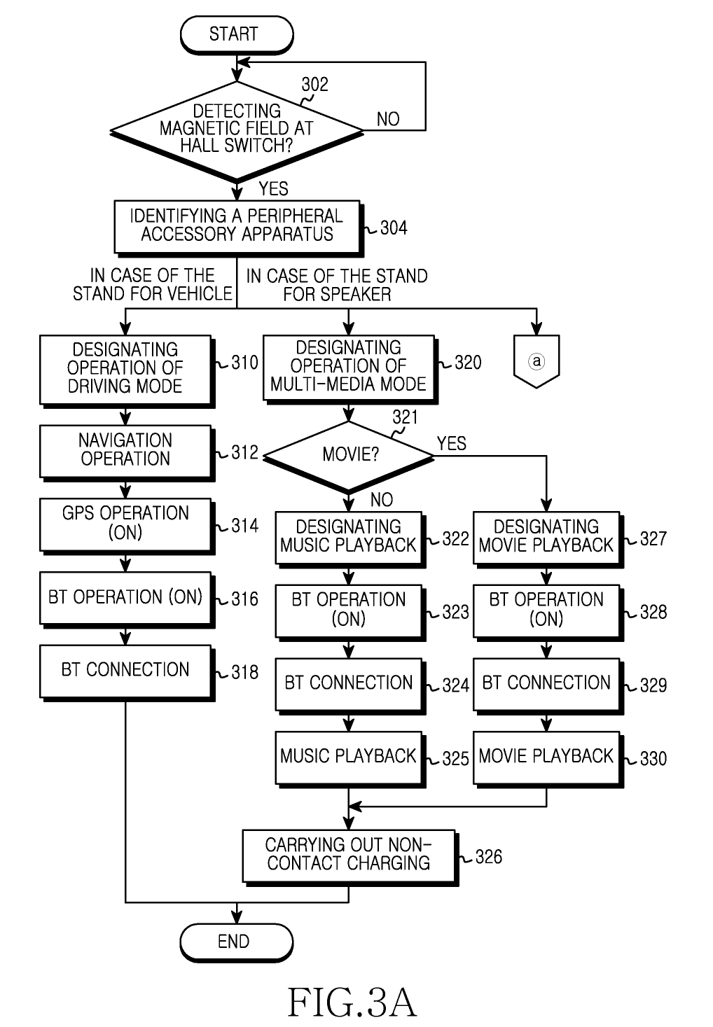

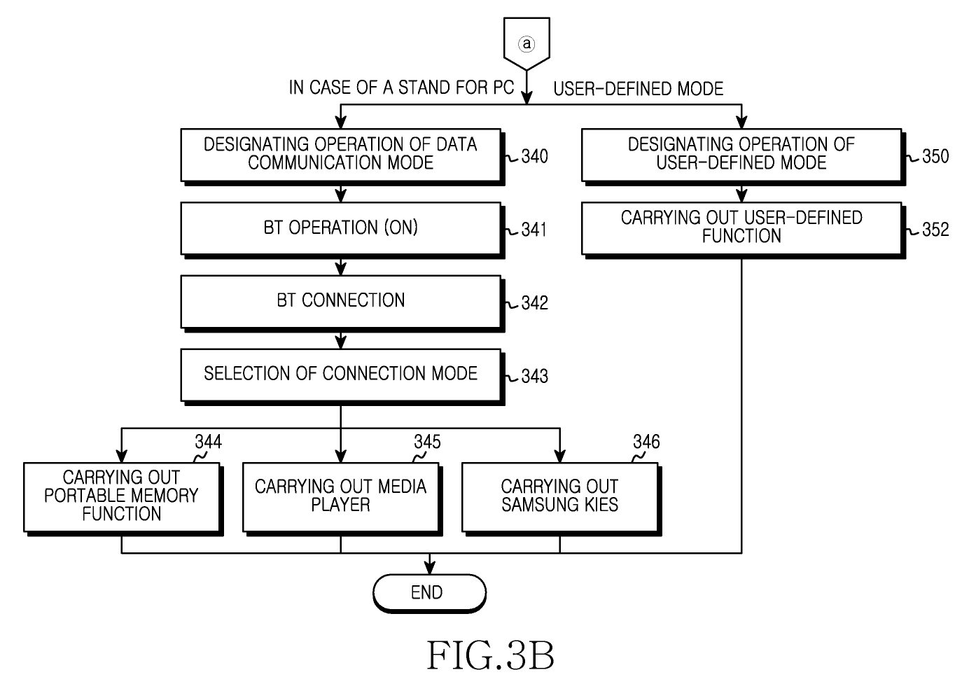

FIGS. 3A and 3B shows a flowchart illustrating a process for identifying a peripheral accessory apparatus of a portable device according to an embodiment of the present invention.

Referring to FIGS. 3A and 3B, when the portable terminal detects magnetic field at Hall Switch (step 302), the portable terminal may identify the type of the peripheral accessory apparatus based on the location of Hall Switch detecting magnetic field sensed (step 304).

If the location of Hall Switch detecting magnetic field corresponds to a stand for a vehicle (210) as shown in FIG. 2, the portable terminal designates the operation of driving mode (step 310) and executes navigation program (step 312).

Thereafter, the portable terminal executes GPS function (step 314) and performs Bluetooth function (step 316) to carry out Bluetooth connection 318 for Bluetooth operation (for example, operating a speaker)

If the location of Hall Switch detecting magnetic corresponds to a speaker stand (220) as shown in FIG. 2, the portable terminal designates the operation of a multimedia mode (step 320). In this case, the portable terminal may be given a function instruction of either movie playback or music playback for a selection by a user.

In case of a music playback (step 321), the portable terminal designates being music playback (step 322) and executes the function of Bluetooth for the operation of Bluetooth (for example, operating a speaker) to carry out Bluetooth connection (step 324). Then, the portable terminal playbacks some music (step 325). During the music playback, the portable terminal may be charged using non-contact charging (step 326).

In case of a movie playback (step 321), the portable terminal activates the movie playback (step 327) and executes the function of Bluetooth (step 328) for operating Bluetooth (step 328) (for example, operating a speaker) to carry out Bluetooth connection (step 329). Then, the portable terminal can playback a movie (step 330). During the movie playback, the portable terminal may be charged using non-contact charging (step 326).

When the location of Hall Switch detecting magnetic corresponds to a PC stand (230) as shown in FIG. 2, the portable terminal designates the operation of data communication mode (step 340), executes Bluetooth function (step 341) for operating Bluetooth (for example, generating communication link) to carry out Bluetooth connection (step 342).

And then, the portable terminal may be given an instruction of connection mode via a selection by the user (step 343).

If the connection mode corresponds to a portable memory mode, the portable terminal executes the portable memory function (step 344).

If the connection mode corresponds to a media player mode, the portable terminal executes the media player function (step 345).

If the connection mode corresponds to the execution mode of Samsung Kies, the portable terminal operates the Samsung Kies program (step 346). Note that Samsung Kies is a software application used to communicate between the latest Samsung devices.

If the portable terminal is set to carry out the function of a user-defined function in the step (step 304), the portable terminal designates on operating user defined mode (step 350) and carries out a particular function defined previously by a user (step 352).

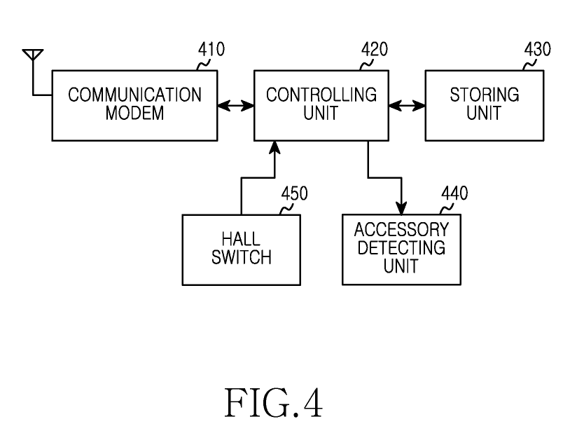

FIG. 4 shows a block configuration according to an embodiment of the present invention.

Referring to FIG. 4, the portable terminal according to the embodiment of the present invention may include a communication modem 410, a controlling unit 420, a storing unit 430, accessory detecting unit 440, and at least one Hall Switch 450.

Although not illustrates, the portable terminal may further include an input unit for input of the user, a displaying unit for displaying information to the user, and a Bluetooth modem for carrying out Near Field Communication (NFC). For illustrative purposes, the Bluetooth modem is shown, but it should be understood that the present invention is not limited to the protocol of Near Field wireless communication but other communication protocol known to artisians can be used.

The communication modem 410 for communicating with other device may comprise a wireless processing unit and a baseband processing unit. The wireless processing unit may convert signal received through an antenna into baseband signal to transmit to the baseband processing unit, and the baseband signal from the baseband processing unit may convert into wireless signal for transmitting the baseband signal on actual wireless network and may transmit the wireless signal through the antenna.

The controlling unit 420 may control the overall operation of the portable terminal and, in particular, may controls an accessory detecting unit 440 according to the present invention.

The storing unit 430 may execute function to store a program for controlling the overall operation of the portable terminal and temporary data generated during execution of the program.

Hall Switch 450 may detect magnetic field of a magnet, and the location of Hall Switch 450 may be defined previously. That is, the function depending on the location may be defined previously as explained with reference to FIG. 2

The accessory detecting unit 440 may execute a previously defined function depending on the location of Hall Switch 450 when Hall Switch 450 detects the magnetic field of a magnet. Here, the user-defined function may be executed.

If the accessory detecting unit 440 detects a magnetic field at a particular Hall Switch 450, the accessory detecting unit 440 may identify a peripheral accessory apparatus type depending on the location of Hall Switch 450 that detects the presence of magnetic field.

If the peripheral accessory apparatus is a stand for vehicle, the accessory detecting unit 440 designates the operation of driving mode and operates a navigation program. Thereafter, the accessory detecting unit 440 may execute GPS function and execute Bluetooth function for the operation of Bluetooth, to carry out Bluetooth connection.

If the peripheral accessory apparatus is a stand for speaker, the accessory detecting unit 440 designates the operation of multi-media mode. During this mode, the accessory detecting unit 440 may be given a function instruction of either a movie playback or a music playback from a user.

If the music playback is selected, the accessory detecting unit 440 executes Bluetooth function for the operation of Bluetooth (for example, operating a speaker) to carry out Bluetooth connection for a replay of desired music.

If the movie playback is selected, the accessory detecting unit 440 executes the function of Bluetooth for operating Bluetooth (for example, operating a speaker) to carry out Bluetooth connection for a replay of a movie.

If the peripheral accessory apparatus is a stand for a PC, the accessory detecting unit 400 designates the operation of data communication mode and executes Bluetooth function for the operation of Bluetooth (for example, generating communication link) to carry out Bluetooth connection. And then, the accessory detecting unit 440 may be given a function instruction of connection mode from a user.

If the connection mode is a portable memory mode, the accessory detecting unit 440 may execute the function of portable memory.

If the connection mode is a media player mode, the accessory detecting unit may execute the function of media player.

If the connection mode is Samsung Kies execution mode, the accessory detecting unit may execute Samsung Kies program.

If the accessory detecting unit 440 is set to carry out a user-defined function, the accessory detecting unit 440 carries out the user-defined function.

In an alternate embodiment, the controlling unit 420 may carry out the function of the accessory detecting unit 440. Thus, some configuration that all the functions of the accessory detecting unit 440 are processed by the controlling unit 420 may be contrived, while other configuration that some functions among all the functions of the accessory detecting unit 420 are processed by the controlling 420 may be contrived.

The present invention may have advantage that a portable device can identify the peripheral accessory apparatus without a contact interfacing with the user, then a function suitable for the accessory apparatus may be execute automatically.

The above-described methods according to the present invention can be implemented in hardware, firmware or as software or computer code that can be stored in a recording medium such as a CD ROM, an RAM, a floppy disk, a hard disk, or a magneto-optical disk or computer code downloaded over a network originally stored on a remote recording medium or a non-transitory machine readable medium and to be stored on a local recording medium, so that the methods described herein can be rendered in such software that is stored on the recording medium using a general purpose computer, or a special processor or in programmable or dedicated hardware, such as an ASIC or FPGA. As would be understood in the art, the computer, the processor, microprocessor controller or the programmable hardware include memory components, e.g., RAM, ROM, Flash, etc. that may store or receive software or computer code that when accessed and executed by the computer, processor or hardware implement the processing methods described herein. In addition, it would be recognized that when a general purpose computer accesses code for implementing the processing shown herein, the execution of the code transforms the general purpose computer into a special purpose computer for executing the processing shown herein.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A method for identifying a device mode type of a terminal having a plurality of hall switches provided at a plurality of predefined locations thereon and being received in a receiver via anon-contact interfacing, the receiver having a plurality of magnets provided at the corresponding locations of the plurality of hall switches, the method comprising:
determining if a particular hall switch located at a particular location detects a magnetic field when a terminal is received in the receiver; and
identifying the device mode type based on when the particular hall switch detects the magnetic field at the particular location.

2. The method of claim 1, the identifying step further comprising:
designating a vehicle mode if the particular location detecting the magnetic field is predetermined to be the vehicle mode;
executing a navigation program; and
performing a Bluetooth connection for an output of sound.

3. The method of claim 1, the identifying step further comprising:
designating a multi-media mode if the particular location detecting the magnetic field is predetermined to be the multi-media mode;
providing a selection choice of either a movie playback or a music playback;
executing a program for the movie playback if the movie playback is selected; and
performing a Bluetooth connection for an output of sound.

4. The method of claim 3, wherein when the music playback is selected,
executing a program for the music playback; and
performing a Bluetooth connection for an output of sound.

5. The method of claim 1, the identifying step further comprising:
executing a program for a data communication if the particular location detecting the magnetic field is predetermined to be a PC mode; and
setting a communication link with an external device.

6. The method of claim 1, further comprising:
executing a user-defined function if one of the plurality of hall switches detects the magnetic field.

7. An apparatus for identifying a device mode via a non-contact interfacing, comprising:
at least one hall switch for detecting a magnetic field at a previously defined location; and
a controlling unit for identifying the device mode based on a location where the at least one hall switch detects the magnetic field.

8. The apparatus of claim 7, wherein the controlling unit designates a vehicle mode if the location where the at least one hall switch detects the magnetic field is predetermined to be the vehicle mode;
executes a navigation program, and
performing a Bluetooth connection for an output of sound.

9. The apparatus of claim 7, wherein the controlling unit designates a multi-media mode if the location where the at least one hall switch detects the magnetic field is predetermined to be the multi-media mode,
determines an selection instruction of either a movie playback or a music playback,
executes a program of the movie playback when the movie playback is selected; and
performing a Bluetooth connection for an output of sound.

10. The apparatus of claim 9, wherein in case of the music playback is selected, the controlling unit executes a program of the music playback and performs a Bluetooth connection for an output of sound.

11. The apparatus of claim 7, wherein the controlling unit executes a program of a data communication if the location where the at least one hall switch detects the magnetic field is predetermined to be a PC mode and establishes a communication link with an external device.

12. The apparatus of claim 7, wherein the controlling unit further executes a user-defined function if one of the hall switches detects the magnetic field.

13. A system for providing a non-contact interface, comprising:
a terminal having a plurality of hall switches provided at a plurality of predefined locations thereon; and
a stand having a plurality of magnets thereon provided at corresponding locations of the plurality of hall switches, so that if a particular hall switch located at the terminal at a particular location detects a magnetic field when the terminal is received in the stand, an operation mode type of the terminal is determined and the terminal operates according to the determination outcome.

14. The system of claim 13, wherein the operation mode type is determined to be a vehicle mode if the particular location detecting the magnetic field is predetermined to be the vehicle mode.

15. The system of claim 13, wherein the terminal executing a navigation program during the vehicle mode.

16. The system of claim 13, wherein the operation mode type is determined to be a multi-media mode if the particular location detecting the magnetic field is predetermined to be the multi-media mode.

17. The system of claim 16, wherein the terminal executes a playback mode during the multi-media mode.

18. The system of claim 13, wherein the operation mode type is determined to be a data communication mode if the particular location detecting the magnetic field is predetermined to be a PC mode.

19. The system of claim 18, wherein the terminal established a communication with an external device during the communication mode.
